(19) United States
(12) Patent Application Publication
(10) Pub. No.: US 2026/0114135 A1
(43) Pub. Date: Apr. 23, 2026

(54) DISPLAY DEVICE INCLUDING A NON-UNIFORM ORGANIC INSULATING LAYER AND ELECTRONIC DEVICE INCLUDING THE SAME

(71) Applicant: SAMSUNG DISPLAY CO., LTD., YONGIN-SI (KR)

(72) Inventors: JUNG-HUN NOH, Yongin-si (KR); HEEJEAN PARK, Yongin-si (KR); DONG-HOON LEE, Yongin-si (KR); SUNGCHUL HONG, Yongin-si (KR)

(21) Appl. No.: 19/281,997

(22) Filed: Jul. 28, 2025

(30) Foreign Application Priority Data
Oct. 23, 2024 (KR) 10-2024-0145959

(51) Int. Cl. H10K 59/123; H10K 59/124

(52) U.S. Cl. CPC H10K 59/123; H10K 59/124

(57) ABSTRACT

A display device including a substrate including a display area; a pixel driving circuit part including at least one transistor disposed on the substrate in the display area; an organic insulating layer disposed on the transistor, wherein the organic insulating layer includes a first upper surface substantially flat in a first area of a light-emitting area of the display area and a second upper surface inclined at a predetermined slope in a second area of the light-emitting area, and wherein a center region of the second upper surface is at a level different than a level of the first upper surface; a pixel electrode disposed on the organic insulating layer; a pixel defining layer having a pixel opening exposing at least a portion of the pixel electrode; and a light-emitting layer disposed in the pixel opening.

### CROSS-REFERENCE TO RELATED APPLICATION

This non-provisional patent application claims priority under 35 U.S.C. § 119 to Korean Patent Application No. 10-2024-0145959, filed on Oct. 23, 2024 in the Korean Intellectual Property Office (KIPO), the entire disclosure of which is incorporated by reference herein in its entirety.

### BACKGROUND

### 1. Technical Field

Embodiments of the present disclosure relate to a display device. More particularly, embodiments of the present disclosure relate to a display device which provides visual information and an electronic device including the same.

### 2. Description of the Related Art

With the advancement of information technology, display devices, which serve as communication media between users and information, are gaining widespread demand. Accordingly, the use of display devices such as a liquid crystal display device, an organic light emitting display device, a plasma display device, and the like is increasing.

### SUMMARY

A display device according to embodiments of the present disclosure includes a substrate including a display area, wherein the display area includes a light-emitting area and a non-light emitting area surrounding the light-emitting area, a pixel driving circuit part including at least one transistor disposed on the substrate in the display area, an organic insulating layer disposed on the transistor, wherein the organic insulating layer includes a first upper surface substantially flat in a first area of the light-emitting area and a second upper surface inclined at a predetermined slope in a second area of the light-emitting area, and wherein a center region of the second upper surface is at a level different than a level of the first upper surface, a pixel electrode disposed on the organic insulating layer, wherein the pixel electrode includes a first electrode pattern overlapping the first area and a second electrode pattern overlapping the second area and connected to the pixel driving circuit part, a pixel defining layer having a pixel opening exposing at least a portion of the pixel electrode, and a light-emitting layer disposed in the pixel opening.

In an embodiment, the second upper surface of the organic insulating layer may have a concave shape. In an embodiment, the second electrode pattern may be integrally formed with the first electrode pattern.

In an embodiment, the pixel opening may include a first sub-opening exposing at least a portion of the first electrode pattern, a second sub-opening exposing at least a portion of the second electrode pattern, and the second sub-opening is spaced apart from the first sub-opening. The light-emitting layer may include a first sub-light emitting layer disposed on the first electrode pattern and a second sub-light emitting layer disposed on the second electrode pattern.

In an embodiment, the second electrode pattern may be spaced apart from the first electrode pattern.

In an embodiment, the pixel driving circuit part may further include a first connection pattern disposed between the transistor and the organic insulating layer in the second area and a second connection pattern disposed between the transistor and the organic insulating layer in the first area, wherein the second connection pattern is connected to the first connection pattern. The first electrode pattern may be connected to the second connection pattern through a first contact hole penetrating the organic insulating layer. The second electrode pattern may be connected to the first connection pattern through a second contact hole penetrating the organic insulating layer.

In an embodiment, the second connection pattern may be integrally formed with the first connection pattern.

In an embodiment, the pixel driving circuit part may further include a connection pattern disposed between the transistor and the organic insulating layer. The connection pattern may include a first portion connected to the first electrode pattern through a first contact hole penetrating the organic insulating layer and a second portion connected to the second electrode pattern through a second contact hole penetrating the organic insulating layer.

In an embodiment, the display device may further include a controller connected to the second portion of the connection pattern, where the controller includes an RLC circuit.

In an embodiment, the pixel driving circuit part may further include a first connection pattern disposed between the transistor and the organic insulating layer in the second area and a second connection pattern disposed between the transistor and the organic insulating layer in the first area, wherein the second connection pattern is spaced apart from the first connection pattern. The first electrode pattern may be connected to the second connection pattern through a first contact hole penetrating the organic insulating layer, and the second electrode pattern may be connected to the first connection pattern through a second contact hole penetrating the organic insulating layer.

In an embodiment, the pixel driving circuit part may include a first sub-pixel driving circuit part connected to the second connection pattern, wherein the first sub-pixel driving circuit includes a first driving transistor and a second sub-pixel driving circuit part connected to the first connection pattern, wherein the second sub-pixel driving circuit includes a second driving transistor.

In an embodiment, an area of the second electrode pattern may be different from an area of the first electrode pattern.

In an embodiment, the light-emitting layer may include a light-emitting material configured to emit one of red light, green light, or blue light.

A display device according to embodiments of the present disclosure includes a substrate including a display area, wherein the display area includes a first light-emitting area, a second light-emitting area, and a third light-emitting area each configured to emit light of different colors and a non-light emitting area surrounding the first light-emitting area, the second light-emitting area, and the third light-emitting area, a pixel driving circuit part including at least one transistor disposed on the substrate in the display area, an organic insulating layer disposed on the transistor, wherein the organic insulating layer includes a first upper surface substantially flat in a first area of each of the first light-emitting area, the second light-emitting area, and the third light-emitting area, and a second upper surface inclined at a predetermined slope in a second area of each of the first light-emitting area, the second light-emitting area, and the third light-emitting area, wherein a center region of the second upper surface is at a level different than a level of the first upper surface, a first pixel electrode, a second pixel electrode, and a third pixel electrode disposed in each of the first light-emitting area, the second light-emitting area, and the third light-emitting area, respectively, on the organic insulating layer, wherein each of the first pixel electrode, the second pixel electrode, and the third pixel electrode includes a first electrode pattern overlapping the first area and a second electrode pattern overlapping the second area and connected to the pixel driving circuit part, a pixel defining layer having a pixel opening exposing at least a portion of each of the first, second, and third pixel electrodes, and a light-emitting layer disposed in the pixel opening.

In an embodiment, the second upper surface of the organic insulating layer may have a concave shape.

In an embodiment, the second electrode pattern may be integrally formed with the first electrode pattern.

In an embodiment, the second electrode pattern may be spaced apart from the first electrode pattern.

In an embodiment, the pixel driving circuit part may include a first pixel driving circuit part, a second pixel driving circuit part, and a third pixel driving circuit part. The first pixel electrode may be connected to the first pixel driving circuit part through a first contact hole, the second pixel electrode may be connected to the second pixel driving circuit part through a second contact hole, and the third pixel electrode may be connected to the third pixel driving circuit part through a third contact hole.

In an embodiment, the first contact hole, the second contact hole, and the third contact hole are sequentially disposed along a first row of the display area, wherein the first contact hole and the third contact hole are sequentially disposed along a first column of the display area, wherein the first column is perpendicular to the first row, and wherein the second contact hole is repeatedly disposed along a second column of the display area, wherein the second column is parallel to the first column.

An electronic device according to embodiments of the present disclosure includes a display device a memory device; and a processor coupled to the memory device, wherein the processor is configured to execute application programs to control the display device. The display device includes a substrate includes a display area, wherein the display area includes a light-emitting area and a non-light emitting area surrounding the light-emitting area, a pixel driving circuit part including at least one transistor disposed on the substrate in the display area, an organic insulating layer disposed on the transistor, wherein the organic insulating layer includes a first upper surface substantially flat in a first area of the light-emitting area and a second upper surface inclined at a predetermined slope in a second area of the light-emitting area, and wherein a center region of the second upper surface is at a level different than a level of the first upper surface, a pixel electrode disposed on the organic insulating layer, wherein the pixel electrode includes a first electrode pattern overlapping the first area and a second electrode pattern overlapping the second area and connected to the pixel driving circuit part, a pixel defining layer having a pixel opening exposing at least a portion of the pixel electrode, and a light-emitting layer disposed in the pixel opening.

In an embodiment, the pixel opening includes a first sub-opening exposing at least a portion of the first electrode pattern, a second sub-opening exposing at least a portion of the second electrode pattern, and the second sub-opening is spaced apart from the first sub-opening, and the light-emitting layer includes a first sub-light emitting layer disposed on the first electrode pattern and a second sub-light emitting layer disposed on the second electrode pattern.

In an embodiment, the pixel driving circuit part further includes a first connection pattern disposed between the transistor and the organic insulating layer in the second area; and a second connection pattern disposed between the transistor and the organic insulating layer in the first area, wherein the second connection pattern is connected to the first connection pattern, wherein the first electrode pattern is connected to the second connection pattern through a first contact hole penetrating the organic insulating layer, and wherein the second electrode pattern is connected to the first connection pattern through a second contact hole penetrating the organic insulating layer.

In an embodiment, the pixel driving circuit part further includes a connection pattern disposed between the transistor and the organic insulating layer; and the connection pattern includes a first portion connected to the first electrode pattern through a first contact hole penetrating the organic insulating layer and a second portion connected to the second electrode pattern through a second contact hole penetrating the organic insulating layer.

In an embodiment, the electronic device includes a controller connected to the second portion of the connection pattern, wherein the controller includes an RLC circuit.

In an embodiment, the pixel driving circuit part further includes a first connection pattern disposed between the transistor and the organic insulating layer in the second area; a second connection pattern disposed between the transistor and the organic insulating layer in the first area, wherein the second connection pattern is spaced apart from the first connection pattern, a first sub-pixel driving circuit part connected to the second connection pattern, wherein the first sub-pixel driving circuit includes a first driving transistor; and a second sub-pixel driving circuit part connected to the first connection pattern, wherein the second sub-pixel driving circuit includes a second driving transistor.

### BRIEF DESCRIPTION OF THE DRAWINGS

FIG. 1 is a plan view illustrating a display device according to embodiments of the present disclosure.

FIG. 2 is an equivalent circuit diagram illustrating one sub-pixel of FIG. 1.

FIG. 3 is an enlarged plan view of region A of FIG. 1.

FIG. 4 is a plan view illustrating a portion corresponding to a light-emitting area of FIG. 3.

FIG. 5 is a cross-sectional view illustrating an example of a cross-section of the light-emitting area taken along line I-I′ of FIG. 4.

FIG. 6 is a cross-sectional view illustrating an example of a cross-section taken along line I-I′ of FIG. 4.

FIG. 7 is a cross-sectional view illustrating an example of a cross-section taken along line I-I′ of FIG. 4.

FIG. 8 is a cross-sectional view illustrating an example of a cross-section taken along line I-I′ of FIG. 4.

FIG. 9 is a plan view illustrating a portion corresponding to a light-emitting area of FIG. 3.

FIG. 10 is a cross-sectional view of the light-emitting area taken along line II-II′ of FIG. 9.

FIG. 11 is a plan view illustrating a portion corresponding to a light-emitting area of FIG. 3.

FIG. 12 is a cross-sectional view of the light-emitting area taken along line III-III′ of FIG. 11.

FIG. 13 is a block diagram illustrating an electronic device including the display device of FIG. 1.

FIG. 14 is a view illustrating an example in which the electronic device of FIG. 13 is implemented as a television.

FIG. 15 is a view illustrating an example in which the electronic device of FIG. 13 is implemented as a smartphone.

### DETAILED DESCRIPTION OF THE EMBODIMENTS

Hereinafter, a display device including a varying organic insulating layer and an electronic device including the display device according to embodiments of the present disclosure are explained in detail with reference to the accompanying drawings. The same reference numerals are used for the same components in the drawings, and redundant descriptions of the same components may be omitted.

It will also be understood that when a layer is referred to as being “on” or “under” another layer or substrate, the layer can be directly on the other layer or substrate, or intervening layers may also be present. For example, when the disclosure describes a first layer disposed on a second layer, then the first layer may be directly disposed on the second layer. In some cases, for example, a third layer may be disposed between the first layer and the second layer. In some aspects, the same reference numbers indicate the same components throughout the specification.

It will be understood that, although the terms “first,” “second,” etc. may be used herein to describe various elements, these elements should not be limited by these terms. These terms are used to distinguish one element from another element. For example, a first element discussed below could be termed a second element without departing from the teachings and spirit of the present disclosure. Similarly, the second element could also be termed the first element.

Each of the features of the various embodiments of the present disclosure may be combined with each other, partially or fully, allowing for various technically interlocking and driving possibilities. Each embodiment may be implemented independently of each other or may be implemented together in an association.

Embodiments of the present disclosure provide a display device including a pixel structure that includes a flat surface and an inclined surface in a light-emitting area. In some embodiments, the display device includes an organic insulating layer having a first upper surface that is substantially flat in a first area of the light-emitting area, and a second upper surface that is inclined (or curved) in a second area of the light-emitting area. A first electrode pattern may be disposed on the first upper surface, and a second electrode pattern may be disposed on the second upper surface, where each of the electrode patterns is electrically connected to each other. In some cases, each electrode pattern is connected to a driving transistor through one or more contact holes.

In some embodiments, the light-emitting layer may include a first sub-light-emitting layer and a second sub-light-emitting layer corresponding to the first upper surface (e.g., flat region) and second upper surface (e.g., the curved region) of the organic insulating layer, respectively. Accordingly, the structural configuration of the organic insulating layer, the electrode pattern, and the emission layer enables the display device of the present disclosure to simultaneously support uniform front luminance and enhanced lateral luminance within a light-emitting area (e.g., single pixel).

In some embodiments, the pixel electrode may be segmented into the first area and the second area of the light-emitting area for independently controlling one or more current paths. A controller circuit (e.g., an RLC circuit) may be electrically coupled to at least one of the electrode patterns to independently control the driving current. By independently controlling the driving current of the pixel electrode in the two areas, the display device of the present disclosure can enhance angular luminance uniformity and viewing angle characteristics.

In a display device according to the embodiments of the present disclosure, an organic insulating layer may have a first upper surface which is substantially flat in a first area of a light-emitting area, and the organic insulating layer may have a second upper surface inclined at a predetermined slope in a second area of the light-emitting area. Because of this, the light-emitting layer in the first area may be substantially flat, and the light-emitting layer in the second area may be inclined to have a predetermined slope. Accordingly, the front luminance seen by the user may be not reduced due to the first area, and the lateral luminance seen by the user may be improved due to the second area.

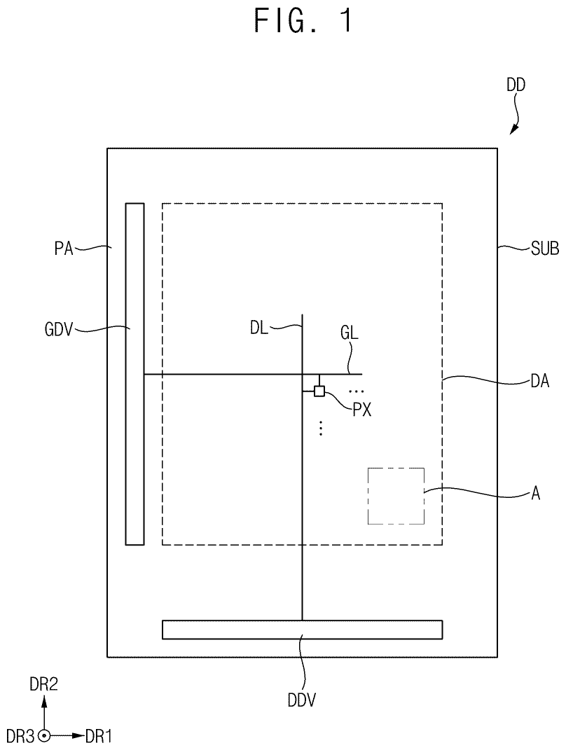

FIG. 1 is a plan view illustrating a display device according to embodiments of the present disclosure. Referring to FIG. 1, the display device DD according to embodiments of the present disclosure may include a substrate SUB, a plurality of pixels PX, a data line DL, a gate line GL, a gate driver GDV, and a data driver DDV.

The substrate SUB may include a display area DA and a peripheral area PA. The display area DA may be an area that can display an image by generating light or adjusting the transmittance of light provided from an external light source. The peripheral area PA may be an area that does not display images. The peripheral area PA may surround the display area DA. For example, the peripheral area PA may entirely surround the display area DA.

A plurality of pixels PX may be arranged in the display area DA on the substrate SUB. The plurality of pixels PX may be arranged in a matrix form along a first direction DR1 and a second direction DR2 intersecting the first direction DR1.

One pixel PX may include a plurality of sub-pixels. For example, the sub-pixels may include a first sub-pixel, a second sub-pixel, and a third sub-pixel which emit light of different colors. For example, the first sub-pixel may emit a red light, the second sub-pixel may emit a green light, and the third sub-pixel may emit a blue light. Each of the sub-pixels may include a driving transistor which generates a driving current and a light-emitting element which is electrically connected to the driving transistor and generates light based on the driving current. Accordingly, each of the sub-pixels may emit light according to the driving current.

Drivers for driving the plurality of pixels PX may be arranged in the peripheral area PA on the substrate SUB. For example, the drivers may include the gate driver GDV and the data driver DDV.

The gate line GL may be electrically connected to the gate driver GDV and may extend along the first direction DR1. The gate line GL may receive a gate signal from the gate driver GDV and transmit the gate signal to the plurality of pixels PX. The gate signal determines when to activate the transistor of a pixel PX, and the gate signals (e.g., a voltage) can be transmitted to the pixel PX to control brightness or color.

The data line DL may be electrically connected to the data driver DDV and may extend along the second direction DR2. The data line DL may receive a data voltage from the data driver DDV and transmit the data voltage to the plurality of pixels PX.

For example, as shown in FIG. 1, the data driver DDV may be directly disposed on the substrate SUB. Alternatively, the data driver DDV may be disposed on a circuit board (e.g., a printed circuit board (PCB) or a flexible printed circuit board (FPCB)) electrically connected to pad electrodes disposed on one side of the peripheral area PA.

As described herein, a plane may be defined as the first direction DR1 and the second direction DR2 intersecting the first direction DR1. For example, the first direction DR1 and the second direction DR2 may be perpendicular to each other. In addition, a third direction DR3 may be perpendicular to the plane formed by the first direction DR1 and the second direction DR2.

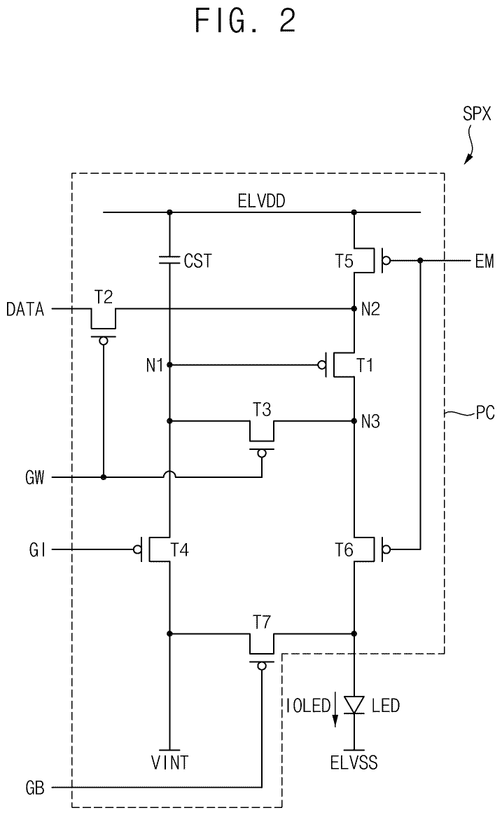

FIG. 2 is an equivalent circuit diagram illustrating one sub-pixel of FIG. 1. Referring to FIG. 2, as described above, one pixel PX of FIG. 1 may include a plurality of sub-pixels. One sub-pixel SPX may include a pixel driving circuit part PC and a light-emitting element LED electrically connected to the pixel driving circuit part PC. The pixel driving circuit part PC may generate a driving current IOLED, and the light-emitting element LED may generate light based on the driving current IOLED.

For example, the pixel driving circuit part PC may include a first transistor T1, a second transistor T2, a third transistor T3, a fourth transistor T4, a fifth transistor T5, a sixth transistor T6, a seventh transistor T7, and a storage capacitor CST. However, embodiments are not limited hereto.

In an embodiment, the first transistor T1, the second transistor T2, the third transistor T3, the fourth transistor T4, the fifth transistor T5, the sixth transistor T6, and the seventh transistor T7 may be PMOS transistors. However, embodiments of the present disclosure are not necessarily limited thereto, and the first transistor T1, the second transistor T2, the fifth transistor T5, the sixth transistor T6, and the seventh transistor T7 may be PMOS transistors, and the third transistor T3 and the fourth transistor T4 may be NMOS transistors. In some cases, PMOS transistors turn on when the gate voltage is low, while NMOS transistors turn on when the gate voltage is high, which enables for complementary switching behavior in circuits.

When the pixel driving circuit part PC includes an NMOS transistor and a PMOS transistor, an active pattern of the NMOS transistor may include an oxide semiconductor, and an active pattern of the PMOS transistor may include a silicon semiconductor. In some embodiments, the active pattern of the NMOS transistor may include a silicon semiconductor, and the active pattern of the PMOS transistor may include an oxide semiconductor.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to a third node N3. The first transistor T1 may provide the driving current IOLED to the light-emitting element LED. The first transistor T1 may be referred to as a driving transistor.

The second transistor T2 may include a gate electrode, a first electrode, and a second electrode. A first gate signal GW may be applied to the gate electrode of the second transistor T2. A data voltage DATA may be applied to the first electrode of the second transistor T2. The second electrode of the second transistor T2 may be connected to the second node N2. In some cases, the second electrode of the second transistor T2 may be connected to the first electrode of the first transistor T1 via the second node N2.

The second transistor T2 may be turned on or off in response to the first gate signal GW. For example, when the first gate signal GW has an activation level, the second transistor T2 may be turned on. For example, the second transistor T2 may provide the data voltage DATA to the second node N2. In some cases, when the first gate signal GW has an inactivation level, the second transistor T2 may be turned off. For example, the second transistor T2 may block the transfer of the data voltage DATA.

The third transistor T3 may include a gate electrode, a first electrode, and a second electrode. The first gate signal GW may be applied to the gate electrode of the third transistor T3. The first electrode of the third transistor T3 may be connected to the third node N3. The second electrode of the third transistor T3 may be connected between the first node N1 and the second electrode of the fourth transistor T4. In some cases, the second electrode of the third transistor T3 may be connected to the first node N1. In some cases, the first electrode of the third transistor T3 may be connected to the second electrode of the first transistor T1 via the third node N3.

The fourth transistor T4 may include a gate electrode, a first electrode, and a second electrode. A second gate signal GI may be applied to the gate electrode of the fourth transistor T4. An initialization voltage VINT may be applied to the first electrode of the fourth transistor T4. The second electrode of the fourth transistor T4 may be connected to the second electrode of the third transistor T3.

The fourth transistor T4 may be turned on or off in response to the second gate signal GI. For example, when the second gate signal GI has an activation level, the fourth transistor T4 may be turned on. For example, the fourth transistor T4 may provide the initialization voltage VINT to the second electrode of the third transistor T3. In some cases, when the second gate signal GI has an inactivation level, the fourth transistor T4 may block the transfer of the initialization voltage VINT.

The fifth transistor T5 may include a gate electrode, a first electrode, and a second electrode. An emission control signal EM may be applied to the gate electrode of the fifth transistor T5. A driving voltage ELVDD may be applied to the first electrode of the fifth transistor T5. The second electrode of the fifth transistor T5 may be connected to the second node N2. In some cases, the second electrode of the fifth transistor T5 may be connected to the first electrode of the first transistor T1 via the second node N2.

The sixth transistor T6 may include a gate electrode, a first electrode, and a second electrode. The emission control signal EM may be applied to the gate electrode of the sixth transistor T6. The first electrode of the sixth transistor T6 may be connected to the third node N3. The second electrode of the sixth transistor T6 may be connected to the second electrode of the seventh transistor T7. In some cases, the first electrode of the sixth transistor T6 may be connected to the second electrode of the first transistor T1 via the third node N3.

The fifth transistor T5 and the sixth transistor T6 may be turned on or off in response to the emission control signal EM. For example, when the emission control signal EM has an activation level, the fifth transistor T5 and the sixth transistor T6 may be turned on. For example, the fifth transistor T5 and the sixth transistor T6 may form a current path for the driving current IOLED generated by the first transistor T1 to the anode electrode of the light-emitting element LED. In some cases, when the emission control signal EM has an inactivation level, the fifth transistor T5 and the sixth transistor T6 may block the transfer of the driving current IOLED generated by the first transistor T1.

The seventh transistor T7 may include a gate electrode, a first electrode, and a second electrode. A third gate signal GB may be applied to the gate electrode of the seventh transistor T7. The initialization voltage VINT may be applied to the first electrode of the seventh transistor T7. The second electrode of the seventh transistor T7 may be connected to the second electrode of the sixth transistor T6. In some cases, the second electrode of the seventh transistor T7 may be connected to the anode electrode of the light-emitting element LED.

The seventh transistor T7 may be turned on or off in response to the third gate signal GB. For example, when the third gate signal GB has an activation level, the seventh transistor T7 may be turned on. For example, the seventh transistor T7 may provide the initialization voltage VINT to the anode electrode of the light-emitting element LED. In some cases, when the third gate signal GB has an inactivation level, the seventh transistor T7 may block the transfer of the initialization voltage VINT.

In an embodiment, the first electrode of each of the first transistor T1, second transistor T2, third transistor T3, fourth transistor T4, fifth transistor T5, sixth transistor T6, and seventh transistor T7 may be a source electrode. In some cases, the second electrode of each of the first transistor T1, second transistor T2, third transistor T3, fourth transistor T4, fifth transistor T5, sixth transistor T6, and seventh transistor T7 may be a drain electrode. However, the embodiments of the present disclosure are not necessarily limited to this, and the first electrode of at least one of the first electrode of each of the first transistor T1, second transistor T2, third transistor T3, fourth transistor T4, fifth transistor T5, sixth transistor T6, or seventh transistor T7 may be a drain electrode. In some cases, at least one of the second electrodes of the first transistor T1, second transistor T2, third transistor T3, fourth transistor T4, fifth transistor T5, sixth transistor T6, and seventh transistor T7 may be source electrodes.

The storage capacitor CST may include a first electrode and a second electrode. The driving voltage ELVDD may be applied to the first electrode of the storage capacitor CST. The second electrode of the storage capacitor CST may be connected to the first node N1. In some cases, the second electrode of the storage capacitor CST may be connected to the gate electrode of the first transistor T1 via the first node N1.

The light-emitting element LED may include an anode electrode and a cathode electrode. The anode electrode of the light-emitting element LED may be connected to the second electrode of the sixth transistor T6 and the second electrode of the seventh transistor T7. The common voltage ELVSS may be applied to the cathode electrode of light-emitting element LED. The common voltage ELVSS may have a lower voltage level than the driving voltage ELVDD.

In FIG. 2, one pixel driving circuit part PC is shown as including seven transistors and one capacitor, but embodiments of the present disclosure are not necessarily limited to the configuration shown in FIG. 2. For example, the pixel driving circuit part PC may include one or more transistors, one or more capacitors, and a light-emitting element LED.

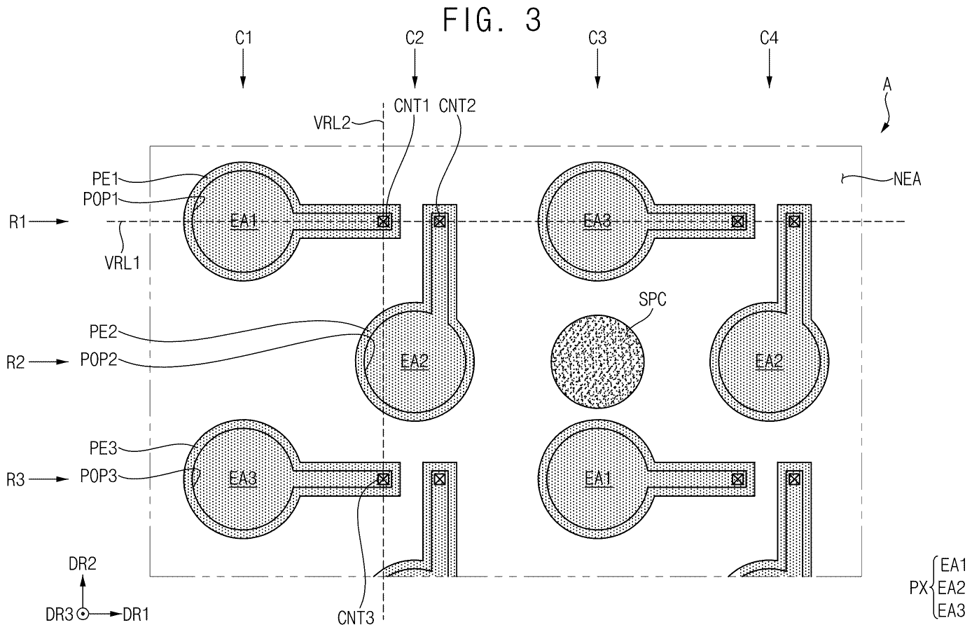

FIG. 3 is an enlarged plan view of region A of FIG. 1. Referring to FIG. 3, the display area DA may include a first light-emitting area EA1, a second light-emitting area EA2, a third light-emitting area EA3, and a non-light emitting area NEA. For example, the first light-emitting area EA1 may emit red light, the second light-emitting area EA2 may emit green light, and the third light-emitting area EA3 may emit blue light. The plurality of pixels PX may be elements which emit light, and each of the pixels PX may include the first, second, and third light-emitting areas EA1, EA2, and EA3. For example, one sub-pixel may be disposed in each of the first, second, and third light-emitting areas EA1, EA2, and EA3. For example, the first light-emitting area EA1 may include the first sub-pixel that emits the red light. The second light-emitting area EA2 may include the second sub-pixel that emits the green light. The third light-emitting area EA3 may include the third sub-pixel that emits the blue light.

The non-light emitting area NEA may surround the first, second, and third light-emitting areas EA1, EA2, and EA3 in a plan view. The non-light emitting area NEA may be an area that does not emit light.

The first, second, and third light-emitting areas EA1, EA2, and EA3 may be arranged in a matrix form along the first direction DR1 and the second direction DR2. In an embodiment, the first, second, and third light-emitting areas EA1, EA2, and EA3 may be arranged in a Pentile™ shape. In some cases, the Pentile™ shape refers to a sub-pixel arrangement in which red, green, and blue sub-pixels are not uniformly repeated in a strict RGB pattern but are instead distributed non-uniformly to share certain sub-pixels.

For example, in a first row R1 of the display area DA, the first light-emitting area EA1 and the third light-emitting area EA3 may be repeatedly arranged in that order along the first direction DR1. In a third row R3 of the display area DA, the third light-emitting area EA3 and the first light-emitting area EA1 may be repeatedly arranged in that order along the first direction DR1. In a second row R2 of the display area DA, the second light emitting area EA2 may be repeatedly arranged along the first direction DR1. This arrangement of light-emitting areas may be repeated up to a predetermined number of rows. Accordingly, the light-emitting areas EA1, EA2, and EA3 may be arranged in a two-dimensional pattern consistent with a Pentile™ sub-pixel layout.

In addition, in a first column C1 of the display area DA, the first light-emitting area EA1 and the third light-emitting area EA3 may repeatedly arranged in the that order along a direction opposite to the second direction DR2. In a third column C3 of the display area DA, the third light-emitting area EA3 and the first light-emitting area EA1 may be repeatedly arranged in that order along the direction opposite to the second direction DR2. In a second column C2 of the display area DA, the second light-emitting area EA2 may be repeatedly arranged along the second direction DR2. Similarly, in the fourth column C4 of the display area DA, the second light-emitting area EA2 may be repeatedly arranged along the second direction DR2. This arrangement of light-emitting areas may be repeated up to a predetermined number of columns.

In some embodiments, each of the light-emitting areas may include a pixel electrode, a contact hole, and a pixel opening. For example, the first light-emitting area EA1 may include a first pixel electrode PE1, a first contact hole CNT1, and a pixel opening POP1. In one aspect, the second light-emitting area EA2 may include a second pixel electrode PE2, a second contact hole CNT2, and a pixel opening POP2. In one aspect, the third light-emitting area EA3 may include a third pixel electrode PE3, a third contact hole CNT3, and a pixel opening POP3.

The display device DD may include a first pixel electrode PE1, a second pixel electrode PE2, and a third pixel electrode PE3. The first pixel electrode PE1 may overlap the first light-emitting area EA1, the second pixel electrode PE2 may overlap the second light-emitting area EA2, and the third pixel electrode PE3 may overlap the third light-emitting area EA3.

Each of the first, second, and third pixel electrodes PE1, PE2, and PE3 may include a reflective electrode. For example, the first, second, and third pixel electrodes PE1, PE2, and PE3 may include metal, alloy, metal nitride, conductive metal oxide, transparent conductive material, or a combination thereof. In an embodiment, each of the first, second, and third pixel electrodes PE1, PE2, and PE3 may have a three-layer structure including ITO/Ag/ITO. For example, the three-layer structure of ITO/Ag/ITO may include a top layer, a middle layer, and a bottom layer. The top layer may include Indium Tin Oxide, the middle layer may include silver, and the bottom layer may include Indium Tin Oxide. However, embodiments of the present disclosure are not necessarily limited thereto.

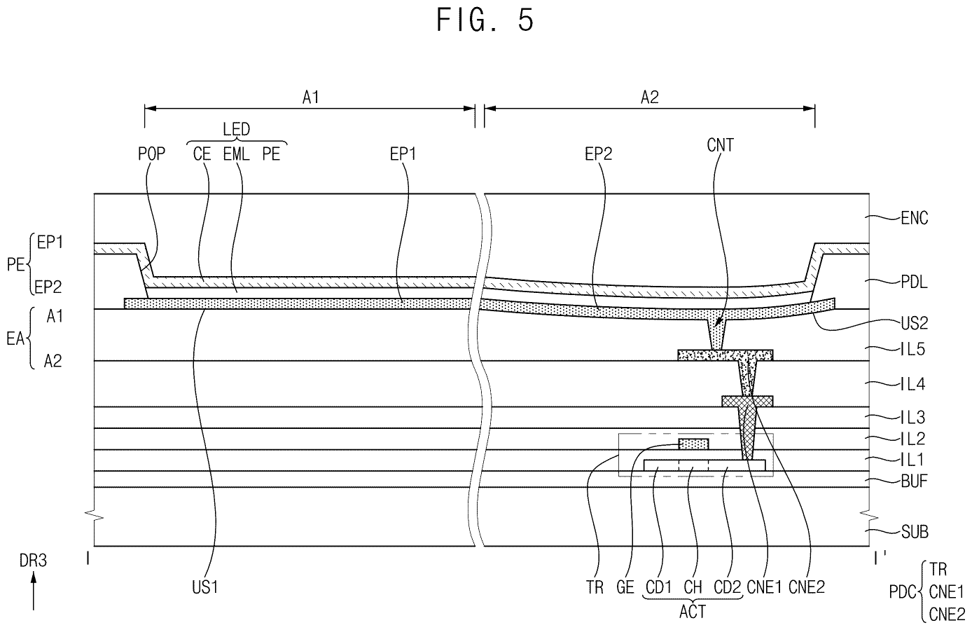

The first pixel electrode PE1 may be electrically connected to a first pixel driving circuit part through a first contact hole CNT1 penetrating an organic insulating layer (e.g., a fifth insulating layer IL5 in FIG. 5). In some cases, the second pixel electrode PE2 may be electrically connected to a second pixel driving circuit part through a second contact hole CNT2 penetrating the organic insulating layer. In some cases, the third pixel electrode PE3 may be connected to a third pixel driving circuit part through a third contact hole CNT3 penetrating the organic insulating layer.

For example, as shown in FIG. 2, each of the first, second, and third pixel driving circuit parts may include seven transistors and one capacitor. However, embodiments of the present disclosure are not necessarily limited to this, and each of the first, second, and third pixel driving circuit parts may include various numbers of transistors and capacitors.

In an embodiment, in a N-th row (e.g., the first row R1 or the third row R3) of the display area DA, the first contact hole CNT1 of the first light-emitting area EA1, the second contact hole CNT2 of the second light-emitting area EA2, the third contact hole CNT3 of the third light-emitting area EA3, and the second contact hole CNT2 of the second light-emitting area EA2 may be repeatedly arranged in that order on a virtual first line VRL1 (e.g., an imaginary line) extending in the first direction DR1. In a M-th column (e.g., the first column C1 or a third column C3) of the display area DA, the first contact hole CNT1 of the first light-emitting area EA1 and the third contact hole CNT3 of the third light-emitting area EA3 may be repeatedly arranged in that order on a virtual second line VRL2 (e.g., an imaginary line) extending in the second direction DR2. In addition, in the M+1-th column (e.g., the second column C2 or the fourth column C4) of the display area DA, the second contact hole CNT2 of the second light-emitting area EA2 may be repeatedly arranged on a virtual line. In some cases, the first, second, and third contact holes CNT1, CNT2, and CNT3 may be spatially aligned in a staggered matrix such that CNT2 is centered between first and third contact holes CNT1 and CNT3 along the first direction DR1.

First, second, and third pixel openings POP1, POP2, and POP3 exposing at least a portion of the first, second, and third pixel electrodes PE1, PE2, and PE3 may be formed in a pixel defining layer (e.g., a pixel defining layer PDL in FIG. 5). For example, the first pixel opening POP1 may expose at least a portion of the first pixel electrode PE1, the second pixel opening POP2 may expose at least a portion of the second pixel electrode PE2, and the third pixel opening POP3 may expose at least a portion of the third pixel electrode PE3. A light-emitting layer may be arranged in each of the first, second, and third pixel openings POP1, POP2, and POP3.

The first, second, and third light-emitting areas EA1, EA2, and EA3 may be formed at least by the first, second, and third pixel openings POP1, POP2, and POP3 of the pixel defining layer, respectively. For example, the size (or width) of the first, second, and third pixel openings POP1, POP2, and POP3 may correspond to the size (or width) of the first, second, and third light-emitting areas EA1, EA2, and EA3, respectively. For example, each of the first, second, and third light-emitting areas EA1, EA2, and EA3 may correspond to the size (or width) of the sub-pixel.

The display device DD may further include a spacer SPC. The spacer SPC may overlap the non-light emitting area NEA. The spacer SPC may prevent a light-emitting element (e.g., the light-emitting element LED in FIG. 5) from being damaged due to sagging of the mask during a process of manufacturing the light-emitting layer using a mask. For example, the spacer SPC may include an organic material. The spacer SPC may have a single-layer or multi-layer structure. In some cases, the spacer SPC may act as a physical support structure to maintain a uniform gap between the mask and the substrate during deposition. In some cases, the spacer SPC may be formed between two second light-emitting areas EA2 adjacent to each other in the first direction DR1. Additionally, the spacer may be formed between the third light-emitting area EA3 and the first light-emitting area EA1 in the second direction in the third column C3.

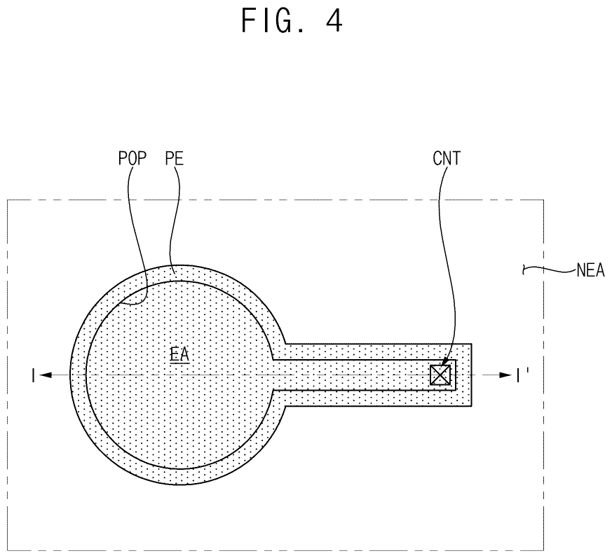

FIG. 4 is a plan view illustrating a portion corresponding to a light-emitting area of FIG. 3. FIG. 5 is a cross-sectional view illustrating an example of a cross-section of the light-emitting area taken along line I-I′ of FIG. 4. Referring to FIGS. 4 and 5, the display device DD according to embodiments of the present disclosure may include a substrate SUB, a buffer layer BUF, a pixel driving circuit part PDC, a first insulating layer IL1, a second insulating layer IL2, a third insulating layer IL3, a fourth insulating layer IL4, and a fifth insulating layer IL5, a pixel defining layer PDL, a light-emitting element LED, and an encapsulation layer ENC. In one aspect, the pixel driving circuit part PDC includes a transistor TR, a first connection pattern CNE1, and a second connection pattern CNE2. In one aspect, the light-emitting element LED includes a pixel electrode PE, a light-emitting layer EML, and a common electrode CE.

The pixel driving circuit part PDC may include a transistor TR, a first connection pattern CNE1, and a second connection pattern CNE2. For example, the transistor TR may include an active pattern ACT and a gate electrode GE. For example, as shown in FIG. 2, the pixel driving circuit part PDC may include seven transistors and one capacitor. However, embodiments of the present disclosure are not necessarily limited thereto. In addition, the light-emitting element LED may include a pixel electrode PE, a light-emitting layer EML, and a common electrode CE.

The substrate SUB may include a transparent material or an opaque material. The substrate SUB may be made of a transparent resin substrate. Examples of the transparent resin substrate include a polyimide substrate. For example, the polyimide substrate may include a first organic layer, a first barrier layer, a second organic layer, and or similar multilayer structures. In some aspects, the substrate SUB may include a quartz substrate, a synthetic quartz substrate, a calcium fluoride substrate, a fluorine-doped quartz substrate, a soda-lime glass substrate, a non-alkali glass substrate, and or combinations thereof.

According to an embodiment, the buffer layer BUF may be disposed on the substrate SUB. The first insulating layer IL1 may be disposed on the buffer layer BUF. However, embodiments are not limited thereto. The buffer layer BUF may prevent metal atoms or impurities from diffusing from the substrate SUB to the transistor TR. In addition, the buffer layer BUF may improve the flatness of the surface of the substrate SUB when the surface of the substrate SUB is not uniform.

The active pattern ACT may be arranged on the buffer layer BUF. In an embodiment, the active pattern ACT may include a metal oxide semiconductor, an inorganic semiconductor (e.g., amorphous silicon, poly silicon, or similar materials), or an organic semiconductor.

The metal oxide semiconductor may include binary compounds (ABₓ), ternary compounds (ABₓC_{y}), or quaternary compounds (ABₓC_{y}D_{z}) including indium (In), zinc (Zn), gallium (Ga), tin (Sn), titanium (Ti), aluminum (Al), hafnium (Hf), zirconium (Zr), magnesium (Mg), or similar elements. For example, the metal oxide semiconductor may include zinc oxide (e.g., ZnO or ZnO₂), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), or combinations thereof.

The active pattern ACT may include a first conductive region CD1, a second conductive region CD2, and a channel region CH disposed and connected between the first conductive region CD1 and the second conductive region CD2. For example, the first conductive region CD1 and the second conductive region CD2 may be doped with impurities (e.g., P-type impurities or N-type impurities). In some cases, the channel region CH may not be doped with impurities.

The first insulating layer IL1 may be disposed on the buffer layer BUF. For example, the first insulating layer IL1 may be directly disposed on the substrate SUB. For example, the first insulating layer IL1 may include an inorganic material such as silicon oxide (SiOₓ), silicon nitride (SiNₓ), silicon oxynitride (SiOₓN_{y}), or combinations thereof. In addition, the first insulating layer IL1 may have a single-layer or multi-layer structure. In some cases, the first insulating layer IL1 may serve both as a barrier layer and a planarization layer to support uniform deposition of subsequent layers.

The gate electrode GE may be disposed on the first insulating layer IL1. The gate electrode GE may overlap the channel region CH of the active pattern ACT in the plan view. The gate electrode GE may include metal, alloy metal nitride, conductive metal oxide, transparent conductive material, or combinations thereof. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or similar elements. Examples of the conductive metal oxide may include indium tin oxide, indium zinc oxide, or similar compounds. In addition, examples of the metal nitride may include aluminum nitride (AlNₓ), tungsten nitride (WNₓ), chromium nitride (CrNₓ), or similar compounds. These can be used individually or in combination with each other. The gate electrode GE may have a single-layer or multi-layer structure.

Accordingly, the transistor TR including the active pattern ACT and the gate electrode GE may be formed within the display area DA. For example, the transistor TR may correspond to the sixth transistor T6 or the seventh transistor T7 of FIG. 2. Alternatively, the transistor TR may correspond to the first transistor T1 of FIG. 2. In some embodiments, the number of transistors included in the pixel driving circuit part PC may be different.

The second insulating layer IL2 may be disposed on the first insulating layer IL1. The second insulating layer IL2 may sufficiently cover the gate electrode GE of the transistor TR and may have a substantially flat upper surface without creating a step around the gate electrode GE. For example, an upper surface of the second insulating layer IL2 may be at a higher level than a level of an upper surface of the transistor TR. In some cases, the second insulating layer IL2 may cover the gate electrode GE and may be conformally deposited along the profile of the gate electrode GE with a uniform thickness. For example, the second insulating layer IL2 may include an inorganic material such as silicon oxide (SiOₓ), silicon nitride (SiNₓ), silicon oxynitride (SiOₓN_{y}), or combinations thereof. The second insulating layer IL2 may have a single-layer or multi-layer structure.

The third insulating layer IL3 may be disposed on the second insulating layer IL2. The third insulating layer IL3 may include an inorganic material such as silicon oxide (SiOₓ), silicon nitride (SiNₓ), silicon oxynitride (SiOₓN_{y}), or combinations thereof. The third insulating layer IL3 may have a single-layer or multi-layer structure.

The first connection pattern CNE1 of the pixel driving circuit part PDC may be disposed on the third insulating layer IL3. The first connection pattern CNE1 may be connected to the second conductive region CD2 of the active pattern ACT through a contact hole penetrating the first, second, and third insulating layers IL1, IL2, and IL3. Accordingly, the first connection pattern CNE1 may be electrically connected to the transistor TR. For example, the first connection pattern CNE1 may include metal, alloy metal nitride, conductive metal oxide, transparent conductive material, or combinations thereof. For example, the first connection pattern CNE1 may have a multilayer structure including at least one of Ti, Al, or Cu. However, embodiments of the present disclosure are not necessarily limited thereto.

The fourth insulating layer IL4 may be disposed on the third insulating layer IL3. The fourth insulating layer IL4 may sufficiently cover the first connection pattern CNE1. For example, the fourth insulating layer IL4 may have a substantially flat upper surface. For example, the fourth insulating layer IL4 may include an organic material such as acrylic resin, benzocyclobutene (BCB), hexamethyldisiloxane (HMDSO), or combinations thereof. The fourth insulating layer IL4 may have a single-layer or multi-layer structure. The fourth insulating layer IL4 may be referred to as an organic insulating layer.

The second connection pattern CNE2 of the pixel driving circuit part PDC may be disposed on the fourth insulating layer IL4. The second connection pattern CNE2 may be connected to the first connection pattern CNE1 through a contact hole penetrating the fourth insulating layer IL4. For example, the second connection pattern CNE2 may include metal, alloy metal nitride, conductive metal oxide, transparent conductive material, or combinations thereof. For example, the second connection pattern CNE2 may have a multilayer structure including at least one of Ti, Al, or Cu. However, embodiments of the present disclosure are not necessarily limited thereto.

The fifth insulating layer IL5 may be disposed on the fourth insulating layer IL4. The fifth insulating layer IL5 may sufficiently cover the second connection pattern CNE2. For example, the fifth insulating layer IL5 may include an organic material such as acrylic resin, benzocyclobutene (BCB), hexamethyldisiloxane (HMDSO), or combinations thereof. The fifth insulating layer IL5 may have a single-layer or multi-layer structure. The fifth insulating layer IL5 may be referred to as an organic insulating layer.

The pixel electrode PE may be disposed on the fifth insulating layer IL5. The pixel electrode PE may be connected to the second connection pattern CNE2 through a contact hole CNT penetrating the fifth insulating layer IL5. The pixel electrode PE may correspond to any one of the first, second, and third pixel electrodes PE1, PE2, and PE3 shown in FIG. 3.

As shown in FIG. 5, the pixel electrode PE may be electrically connected to the transistor TR through two connection patterns. For example, the pixel electrode PE may be electrically connected to the transistor TR through second connection pattern CNE2 and a first connection pattern CNE1 formed in the fourth insulating layer IL4 and the third insulating layer IL3, respectively. However, embodiments of the present disclosure are not necessarily limited to this, and the pixel electrode PE may be electrically connected to the transistor TR through one connection pattern. For example, the display device DD may include one organic insulating layer (e.g., the fourth insulating layer IL4 or the fifth insulating layer IL5) and one connection pattern (e.g., the first connection pattern CNE1 or the second connection pattern CNE2).

The pixel defining layer PDL may be disposed on the fifth insulating layer IL5 and the pixel electrode PE. The pixel defining layer PDL may cover an edge of the pixel electrode PE. In addition, a pixel opening POP exposing at least a portion of the pixel electrode PE may be formed in the pixel defining layer PDL. For example, the pixel defining layer PDL may include an organic material such as polyimide resin, hexamethyldisiloxane (HMDSO), or combinations thereof. Alternatively, the pixel defining layer PDL may include an inorganic material.

A light-emitting area EA may be formed by the pixel opening POP of the pixel defining layer PDL. For example, the width of the pixel opening POP may correspond to the width of the light-emitting area EA. The light-emitting area EA may correspond to any one of the first, second, and third light-emitting areas EA1, EA2, and EA3 shown in FIG. 3.

In an embodiment, the pixel opening POP may continuously extend throughout the light-emitting area EA. However, embodiments of the present disclosure are not necessarily limited thereto. The light-emitting area EA may include a first area A1 and a second area A2. In an embodiment, the fifth insulating layer IL5 may have a first upper surface US1 which is substantially flat in the first area A1 and a second upper surface US2 inclined to have a predetermined slope in the second area A2.

For example, the second upper surface US2 of the fifth insulating layer IL5 may have a concave shape. For example, the second upper surface US2 of the fifth insulating layer IL5 may be recessed toward the substrate SUB. In some cases, the second upper surface US2 of the fifth insulating layer IL5 may have a convex shape. In some cases, the second upper surface US2 of the fifth insulating layer IL5 may protrude toward the pixel electrode PE.

For example, the second upper surface US2 of the fifth insulating layer IL5 may have a curved shape in a cross-section view. For example, the second upper surface US2 of the fifth insulating layer IL5 may have a concave or convex curved shape in the cross-section view. In some embodiments, the second upper surface US2 of the fifth insulating layer IL5 may include a flat portion located at the center and an inclined portion located at an edge where the inclined portion extends in a straight line from the flat portion at a predetermined slope.

The pixel electrode PE may include a first electrode pattern EP1 and a second electrode pattern EP2. The first electrode pattern EP1 may be disposed in the first area A1, and the second electrode pattern EP2 may be disposed in the second area A2. In addition, the second electrode pattern EP2 may be connected to the second connection pattern CNE2 through the contact hole CNT. Accordingly, the second electrode pattern EP2 may be electrically connected to the pixel driving circuit part PDC. In some cases, the first electrode pattern EP1 may serve as the light-emitting region of the pixel electrode PE, while the second electrode pattern EP2 may serve as the electrical connection path to the driving circuit. In some cases, the first electrode pattern EP1 and the second electrode pattern EP2 may be light-emitting region of the pixel electrode PE.

In an embodiment, the first electrode pattern EP1 may be integrated with the second electrode pattern EP2. However, embodiments of the present disclosure are not necessarily limited thereto. In an embodiment, the first electrode pattern EP1 may be integrally formed with the second electrode pattern EP2. For example, the first electrode pattern EP1 and the second electrode pattern EP2 may be manufactured as a continuous conductive structure.

In an embodiment, the area of the second electrode pattern EP2 may be different from the area of the first electrode pattern EP1. For example, the area of the second area A2 may be different from the area of the first area A1. However, embodiments of the present disclosure are not necessarily limited to this, and the area of the second electrode pattern EP2 may be substantially the same as the area of the first electrode pattern EP1. For example, the area of the second area A2 may be substantially the same as the area of the first area A1.

In an embodiment, as the second upper surface US2 of the fifth insulating layer IL5 is inclined at a predetermined slope, a portion of the pixel electrode PE overlapping the second area A2 (e.g., the second electrode pattern EP2) may also be inclined at the predetermined slope. For example, the second electrode pattern EP2 may be conformally disposed along the profile of the second upper surface US2 of the fifth insulating layer IL5.

The light-emitting layer EML may be disposed on the pixel electrode PE. For example, the light-emitting layer EML may be disposed in the pixel opening POP. For example, the light-emitting layer EML may include a light-emitting material which emits a light (e.g., red light, green light, or blue light). In an embodiment, the light-emitting layer EML may continuously extend throughout the light-emitting area EA. However, embodiments of the present disclosure are not necessarily limited thereto.

In an embodiment, as the second electrode pattern EP2 is inclined at a predetermined slope, a portion of the light-emitting layer EML overlapping the second area A2 may also be inclined at the predetermined slope. For example, in the second area A2, the light-emitting layer EML may be conformally deposited along the profile of the second electrode pattern EP2.

The common electrode CE may be disposed on the light-emitting layer EML and the pixel defining layer PDL. The common electrode CE may be formed to cover the entire surface of the display area DA (e.g., including an upper surface of the pixel defining layer PDL and an upper surface of the light-emitting layer EML). The common electrode CE may include a semi-transmissive or transmissive electrode. For example, the common electrode CE may include a conductive material with a low work function.

In an embodiment, as the portion of the light-emitting layer EML overlapping the second area A2 is inclined at a predetermined slope, the portion of the common electrode CE overlapping the second area A2 may also be inclined at the predetermined slope. For example, in the second area A2, the common electrode CE may be conformally formed along the profile of the light-emitting layer EML.

Accordingly, the light-emitting element LED including the pixel electrode PE, the light-emitting layer EML, and the common electrode CE may be formed on the transistor TR. The light-emitting element LED may be electrically connected to the transistor TR through the connection pattern (e.g., the first connection pattern CNE1 and the second connection pattern CNE2).

The encapsulation layer ENC may be disposed on the common electrode CE. The encapsulation layer ENC may prevent impurities, moisture, and other contaminants from penetrating into the light-emitting element LED from the outside. The encapsulation layer ENC may include at least one inorganic encapsulation layer and at least one organic encapsulation layer. For example, the encapsulation layer ENC may include a first inorganic encapsulation layer disposed on the common electrode CE, a second inorganic encapsulation layer disposed on the first inorganic encapsulation layer, and an organic encapsulation layer disposed between the first inorganic encapsulation layer and the second inorganic encapsulation layer. In some cases, the encapsulation layer ENC may include a single layer structure. In some cases, an upper surface of the encapsulation layer ENC may be substantially flat.

In the display device DD according to the embodiments of the present disclosure, the organic insulating layer (e.g., the fifth insulating layer IL5) may have the first upper surface US1 which is substantially flat in the first area A1 of the light-emitting area EA, and the organic insulating layer may have the second upper surface US2 inclined at a predetermined slope in the second area A2 of the light-emitting area EA. As a result, the light-emitting layer EML in the first area A1 may be substantially flat, and the light-emitting layer EML in the second area A2 may be inclined at the predetermined slope. Accordingly, the front luminance observed by a user may be maintained in the first area A1, and the lateral luminance may be enhanced in the second area A2. The non-uniformness of the organic insulating layer leads to a uniform brightness profile and improved viewing angles across the display device DD.

According to some embodiments, the fifth insulating layer IL5 including the first upper surface US1 and the second upper surface US2 may provide both optical and structural benefits. For example, the flat first upper surface US1 in the first area A1 may support uniform film thickness, thereby maintaining high front luminance as observed along a normal viewing direction. In some cases, the second upper surface US2 in the second area A2 may redirect a portion of the emitted light toward lateral viewing angles, thereby enhancing lateral luminance and improving viewing angle performance. In some embodiments, a center region of the second upper surface US2 may be at a level lower than the first upper surface US1. The end regions of the second upper surface US2 may be at a level substantially the same as the first upper surface US1. In some embodiments, the center region of the second upper surface US2 may be at a level higher than a level of the first upper surface US1.

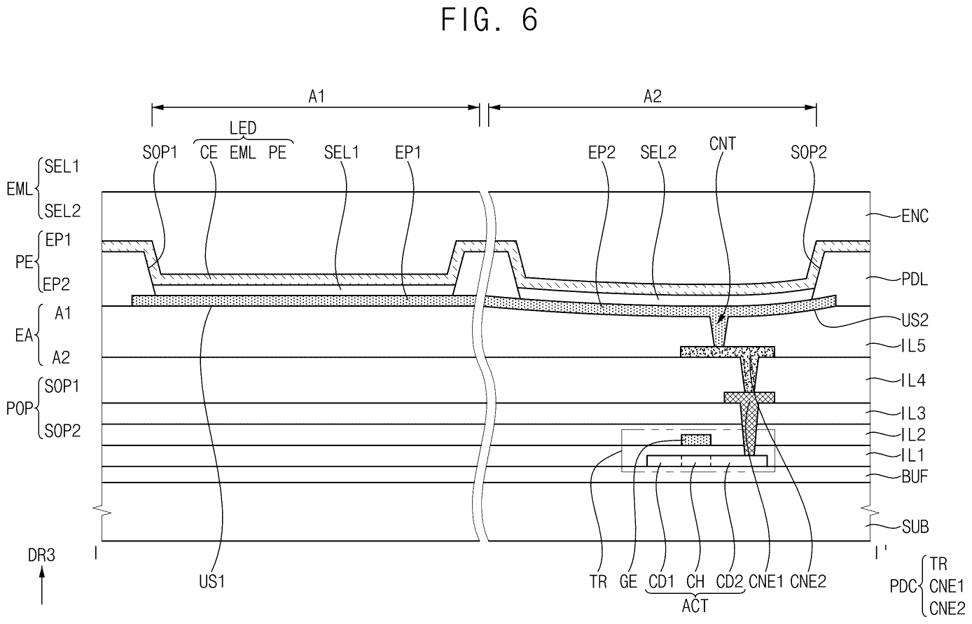

FIG. 6 is a cross-sectional view illustrating an example of a cross-section taken along line I-I′ of FIG. 4. Referring to FIG. 6, a display device according to embodiments of the present disclosure may include a substrate SUB, a buffer layer BUF, a pixel driving circuit part PDC, a first insulating layer IL1, a second insulating layer IL2, a third insulating layer IL3, a fourth insulating layer IL4, and a fifth insulating layer IL5, a pixel defining layer PDL, a light-emitting element LED, and an encapsulation layer ENC. The pixel driving circuit part PDC may include a transistor TR, a first connection pattern CNE1, and a second connection pattern CNE2. For example, the transistor TR may include an active pattern ACT and a gate electrode GE. In addition, the light-emitting element LED may include a pixel electrode PE, a light-emitting layer EML, and a common electrode CE.

However, the display device DD described with reference to FIG. 6 may be substantially the same as or similar to the display device DD described with reference to FIGS. 4 and 5 except for the pixel defining layer PDL and the light-emitting layer EML. Hereinafter, overlapping descriptions are omitted or simplified.

The pixel electrode PE may include a first electrode pattern EP1 overlapping the first area A1 and a second electrode pattern EP2 overlapping the second area A2. In an embodiment, the first electrode pattern EP1 may be integrally formed with the second electrode pattern EP2. In one aspect, the first electrode pattern EP1 may be disposed on a flat surface corresponding to the first upper surface US1 of the fifth insulating layer IL5, and the second electrode pattern EP2 may disposed on an inclined region in the second upper surface US2 of the fifth insulating layer IL5.

A pixel opening POP exposing at least a portion of the pixel electrode PE may be formed in the pixel defining layer PDL. In an embodiment, the pixel opening POP may include a first sub-opening SOP1 exposing at least a portion of the first electrode pattern EP1 and a second sub-opening SOP2 exposing at least a portion of the second electrode pattern EP2 and spaced apart from the first sub-opening SOP1. For example, the pixel defining layer PDL may cover the edges of the first electrode pattern EP1 and the edges of the second electrode pattern EP2.

The light-emitting layer EML may be disposed within the pixel opening POP. In an embodiment, the pixel opening POP including the first sub opening SOP1 and the second sub opening SOP2, the light-emitting layer EML including a first sub-light emitting layer SEL1 is disposed in the first sub-opening SOP1 and a second sub-light emitting layer SEL2 is disposed in the second sub-opening SOP2. For example, the second sub-light emitting layer SEL2 may be spaced apart from the first sub-light emitting layer SEL1. The second sub-light emitting layer SEL2 may include a light-emitting material which emits light of the same color as the first sub-light emitting layer SEL1. In some cases, the segmentation of the EML into separated sub-light-emitting regions (e.g., the first sub-light emitting layer SEL1 and the second sub-light emitting layer SEL2) may correspond to respective regions within the pixel electrode PE and enables light to be emitted from multiple emission surfaces across different elevations or slopes.

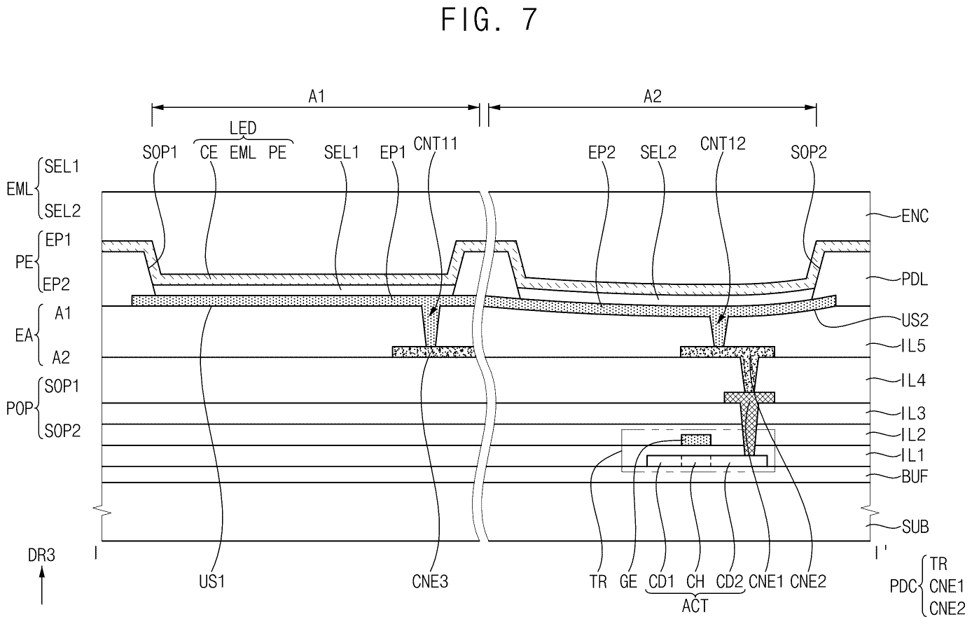

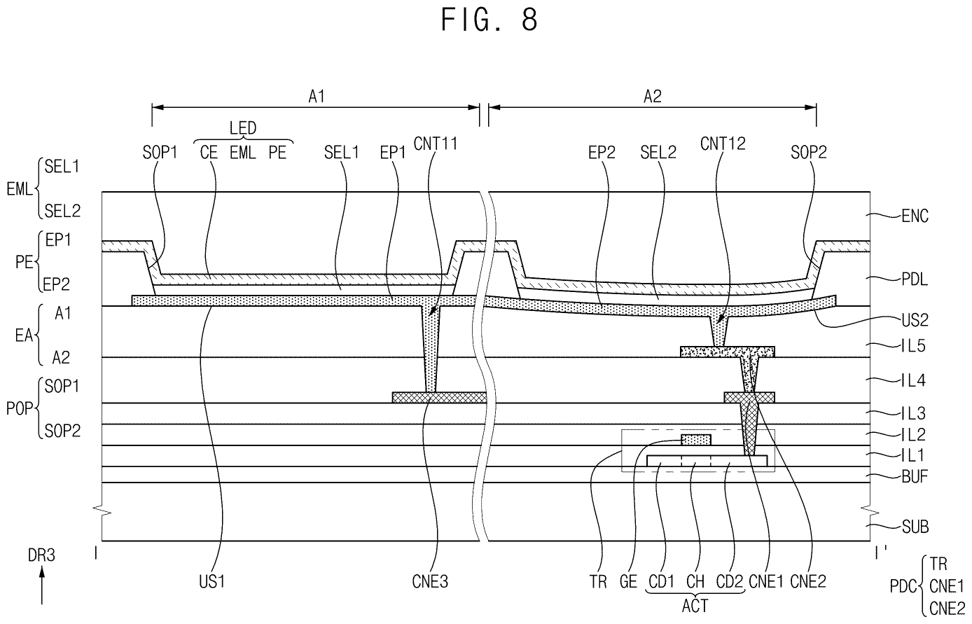

FIG. 7 is a cross-sectional view illustrating an example of a cross-section taken along line I-I′ of FIG. 4. FIG. 8 is a cross-sectional view illustrating an example of a cross-section taken along line I-I′ of FIG. 4. Referring to FIGS. 7 and 8, a display device according to embodiments of the present disclosure may include a substrate SUB, a buffer layer BUF, a pixel driving circuit part PDC, a first insulating layer IL1, a second insulating layer IL2, a third insulating layer IL3, a fourth insulating layer IL4, and a fifth insulating layer IL5, a third connection pattern CNE3, a pixel defining layer PDL, a light-emitting element LED, and an encapsulation layer ENC. The pixel driving circuit part PDC may include a transistor TR, a first connection pattern CNE1, and a second connection pattern CNE2. For example, the transistor TR may include an active pattern ACT and a gate electrode GE. In addition, the light-emitting element LED may include a pixel electrode PE, a light-emitting layer EML, and a common electrode CE.

However, the display device described with reference to FIGS. 7 and 8 may be substantially the same as or similar to the display device described with reference to FIG. 6 except for the pixel electrode PE and the third connection pattern CNE3. Hereinafter, overlapping descriptions are omitted or simplified.

The pixel electrode PE may include a first electrode pattern EP1 overlapping the first area A1 and a second electrode pattern EP2 overlapping the second area A2. In an embodiment, the first electrode pattern EP1 may not be formed integrally with the second electrode pattern EP2. For example, the first electrode pattern EP1 may be spaced apart from the second electrode pattern EP2. Accordingly, in one light-emitting area EA, the light-emitting element LED may be divided into two light-emitting elements.

As shown in FIG. 7, in an embodiment, the first electrode pattern EP1 may be connected to the third connection pattern CNE3 through a first-first contact hole CNT11 penetrating the fifth insulating layer IL5, and the second electrode pattern EP2 may be connected to the second connection pattern CNE2 through a first-second contact hole CNT12 penetrating the fifth insulating layer IL5. The third connection pattern CNE3 may be connected to the second connection pattern CNE2. For example, the third connection pattern CNE3 may be integrally formed with the second connection pattern CNE2. For example, the third connection pattern CNE3 may be disposed in the same layer as the second connection pattern CNE2 and may be formed through the same process. Accordingly, the first electrode pattern EP1 may be electrically connected to the second electrode pattern EP2, and the pixel electrode PE (including the first electrode pattern EP1 and the second electrode pattern EP2) may be electrically connected to the transistor TR.

As shown in FIG. 8, in an embodiment, the first electrode pattern EP1 may be connected to the third connection pattern CNE3 through a first-first contact hole CNT11 penetrating the fourth and fifth insulating layers IL4 and IL5, and the second electrode pattern EP2 may be connected to the second connection pattern CNE2 through a first-second contact hole CNT12 penetrating the fifth insulating layer IL5. The third connection pattern CNE3 may be connected to the first connection pattern CNE1. For example, the third connection pattern CNE3 may be integrally formed with the first connection pattern CNE1. For example, the third connection pattern CNE3 may be disposed in the same layer as the first connection pattern CNE1 and may be formed through the same process. Accordingly, the first electrode pattern EP1 may be electrically connected to the second electrode pattern EP2, and the pixel electrode PE (including the first electrode pattern EP1 and the second electrode pattern EP2) may be electrically connected to the transistor TR.

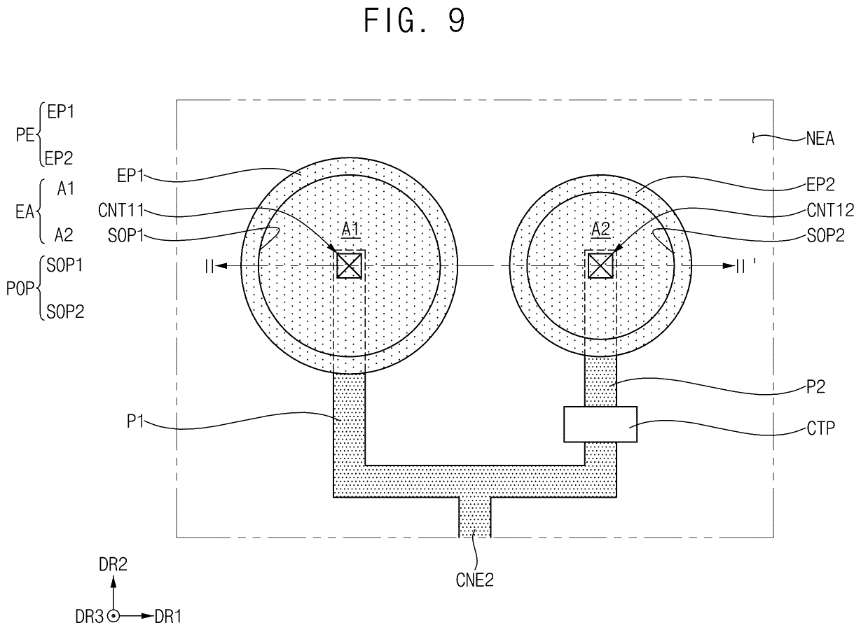

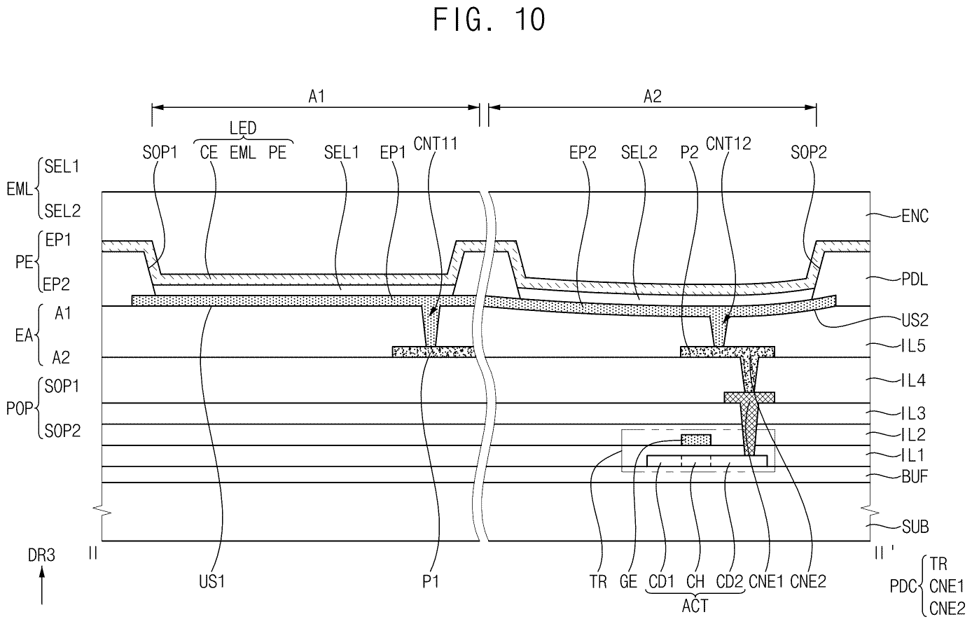

FIG. 9 is a plan view illustrating a portion corresponding to a light-emitting area of FIG. 3. FIG. 10 is a cross-sectional view of the light-emitting area taken along line II-II′ of FIG. 9.

Referring to FIGS. 9 and 10, a display device according to embodiments of the present disclosure may include a substrate SUB, a buffer layer BUF, a pixel driving circuit part PDC, a first insulating layer IL1, a second insulating layer IL2, a third insulating layer IL3, a fourth insulating layer IL4, and a fifth insulating layer IL5, a pixel defining layer PDL, a light-emitting element LED, an encapsulation layer ENC, and a controller CTP. The pixel driving circuit part PDC may include a transistor TR, a first connection pattern CNE1, and a second connection pattern CNE2. For example, the transistor TR may include an active pattern ACT and a gate electrode GE. In addition, the light-emitting element LED may include a pixel electrode PE, a light-emitting layer EML, and a common electrode CE.

The display device described with reference to FIGS. 9 and 10 may be substantially the same as or similar to the display device described with reference to FIG. 7 except that the display device further includes the controller CTP. Hereinafter, overlapping descriptions are omitted or simplified.

The pixel electrode PE may include a first electrode pattern EP1 overlapping the first area A1 and a second electrode pattern EP2 overlapping the second area A2. In an embodiment, the first electrode pattern EP1 may not be formed integrally with the second electrode pattern EP2. For example, the first electrode pattern EP1 may be spaced apart from the second electrode pattern EP2. Accordingly, in one light-emitting area EA, the light-emitting element LED may be divided into two light-emitting elements. In some cases, the first and second light-emitting elements may be independently controlled and may emit different color lights. In some cases, the first and second light-emitting elements may emit the same color light.

In an embodiment, the second connection pattern CNE2 may be extended to a first portion P1 connected to the first electrode pattern EP1 in the first area A1 through a first-first contact hole CNT11 penetrating the fifth insulating layer IL5. The second connection pattern CNE2 may be extended to a second portion P2 connected to the second electrode pattern EP2 through a first-second contact hole CNT12 penetrating the fifth insulating layer IL5. Accordingly, the first electrode pattern EP1 may be electrically connected to the second electrode pattern EP2, and the pixel electrode PE (including the first electrode pattern EP1 and the second electrode pattern EP2) may be electrically connected to the transistor TR.

In an embodiment, the controller CTP may be connected to the second portion P2 of the second connection pattern CNE2 and may include an RLC circuit. As the controller CTP includes the RLC circuit, different driving currents may be applied to the first electrode pattern EP1 and the second electrode pattern EP2. For example, the first electrode pattern EP1 and the second electrode pattern EP2 may be driven independently of each other. For example, the RLC circuit refers to a circuit including a resistor, an inductor, and a capacitor. In some cases, the RLC circuit may introduce phase or frequency-dependent control over the current supplied to the second portion P2, and thus, the first electrode pattern EP1 and the second electrode pattern EP2 can be independently driven.

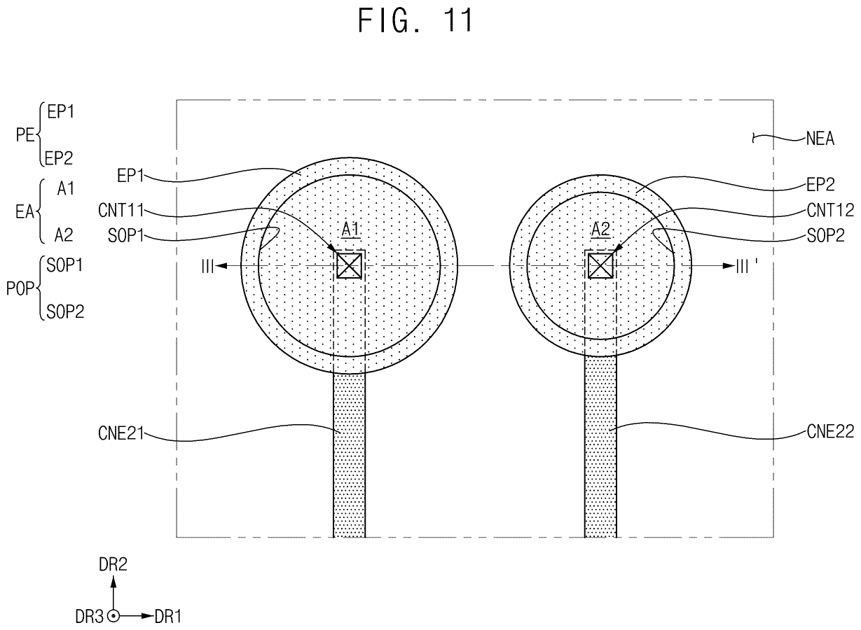

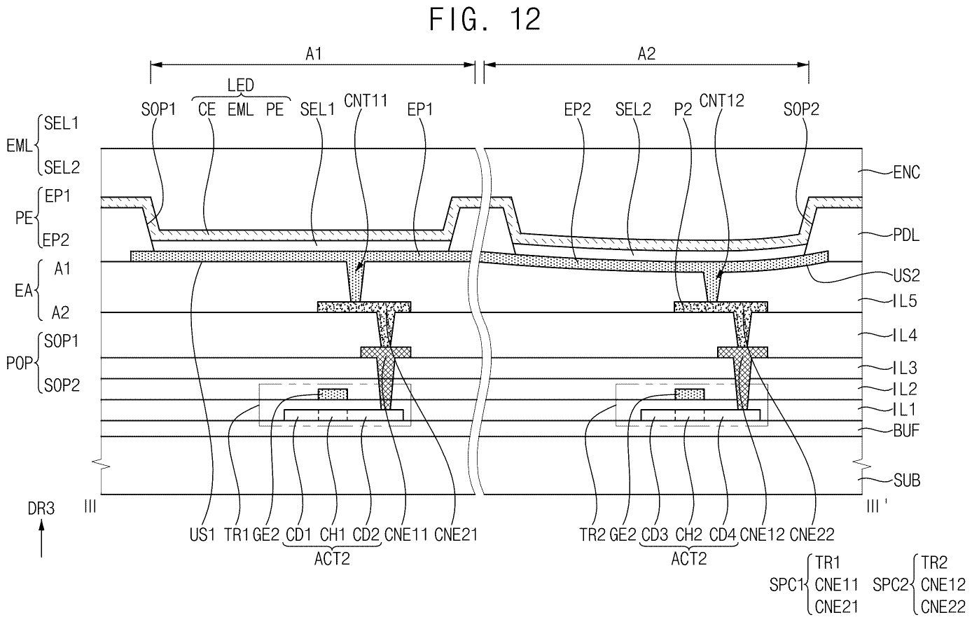

FIG. 11 is a plan view illustrating a portion corresponding to a light-emitting area of FIG. 3. FIG. 12 is a cross-sectional view of the light-emitting area taken along line III-III′ of FIG. 11.

Referring to FIGS. 11 and 12, a display device according to embodiments of the present disclosure may include a substrate SUB, a buffer layer BUF, a first sub-pixel driving circuit part SPC1, a second sub-pixel driving circuit part SPC2, a first insulating layer IL1, a second insulating layer IL2, a third insulating layer IL3, a fourth insulating layer IL4, and a fifth insulating layer IL5, a pixel defining layer PDL, a light-emitting element LED, and an encapsulation layer ENC. The first sub-pixel driving circuit part SPC1 may include a first transistor TR1, a first-first connection pattern CNE11, and a second-first connection pattern CNE21, and the second sub-pixel driving circuit part SPC2 may include a second transistor TR2, a first-second connection pattern CNE12, and a second-second connection pattern CNE22. In some aspects, the configurations of the first sub-pixel driving circuit part SPC1 and the second sub-pixel driving circuit part SPC2 may be substantially the same.

For example, the first transistor TR1 may include a first active pattern ACT1 and a first gate electrode GE1, and the second transistor TR2 may include a second active pattern ACT2 and a second gate electrode GE2. In addition, the light-emitting element LED may include a pixel electrode PE, a light-emitting layer EML, and a common electrode CE.

In some embodiments, the display device described with reference to FIGS. 11 and 12 may be substantially the same as or similar to the display device described with reference to FIG. 7 except for the first sub-pixel driving circuit part SPC1 and the second sub-pixel driving circuit part SPC2. Hereinafter, overlapping descriptions are omitted or simplified.

The first and second active patterns ACT1 and ACT2 may be disposed on the buffer layer BUF. The first active pattern ACT1 may include a first conductive region CD1, a second conductive region CD2, and a first channel region CH1 disposed between the first conductive region CD1 and the second conductive region CD2. The second active pattern ACT2 may include a third conductive region CD3, a fourth conductive region CD4, and a second channel region CH2 disposed between the third conductive region CD3 and fourth conductive region CD4. The first and second active patterns ACT1 and ACT2 may be substantially the same as the active pattern ACT shown in FIG. 5.

The first and second gate electrodes GE1 and GE2 may be disposed on the first insulating layer IL1. The first gate electrode GE1 may overlap the first channel region CH1, and the second gate electrode GE2 may overlap the second channel region CH2. The first and second gate electrodes GE1 and GE2 may be substantially the same as the gate electrode GE of FIG. 5.

Accordingly, the first transistor TR1 and the second transistor TR2 may be formed. For example, the first transistor TR1 and the second transistor TR2 may correspond to the sixth transistor T6 and the seventh transistor T7 of FIG. 2, respectively.

The first-first and first-second connection patterns CNE11 and CNE12 are spaced apart from each other along the first direction DR1 and may be disposed on the third insulating layer IL3. The first-first connection pattern CNE11 may be connected to the second conductive area CD2, and the first-second connection pattern CNE12 may be connected to the fourth conductive area CD4. The first-first and first-second connection patterns CNE11 and CNE12 may be substantially the same as the first connection pattern CNE1 of FIG. 5.

The second-first and second-second connection patterns CNE21 and CNE22 are spaced apart from each other along the first direction DR1 and may be arranged on the fourth insulating layer IL4. The second-first connection pattern CNE21 may be connected to the first-first connection pattern CNE11, and the second-second connection pattern CNE22 may be connected to the first-second connection pattern CNE12. The second-first and second-second connection patterns CNE21 and CNE22 may be substantially the same as the second connection pattern CNE2 of FIG. 5.

The pixel electrode PE may include a first electrode pattern EP1 overlapping the first area A1 and a second electrode pattern EP2 overlapping the second area A2. In an embodiment, the first electrode pattern EP1 may not be formed integrally with the second electrode pattern EP2. For example, the first electrode pattern EP1 may be spaced apart from the second electrode pattern EP2. Accordingly, in one light-emitting area EA, the light-emitting element LED may be divided into two light-emitting elements. In some cases, the first and second light-emitting elements may emit the different color lights. In some cases, the first and second light-emitting elements may emit the same color light.

In an embodiment, the first electrode pattern EP1 may be connected to the second-first connection pattern CNE21 through a first-first contact hole CNT11 penetrating the fifth insulating layer IL5. Additionally, the second electrode pattern EP2 may be connected to the second-second connection pattern CNE22 through a first-second contact hole CNT12 penetrating the fifth insulating layer IL5. Accordingly, the first electrode pattern EP1 may not be electrically connected to the second electrode pattern EP2. For example, different driving currents may be applied to the first electrode pattern EP1 and the second electrode pattern EP2. As a result, the first electrode pattern EP1 and the second electrode pattern EP2 may be driven independently of each other.

The display device of FIGS. 11 and 12 may include two sub-pixel driving circuit parts in one light-emitting area EA which emits any one of red light, red light, and blue light. Each of the sub-pixel driving circuit parts SPC1 and SPC1 may have substantially the same circuit structure as the pixel driving circuit part PC of FIG. 2. For example, the first sub-pixel driving circuit part SPC1 may include a first driving transistor, and the second sub-pixel driving circuit part SPC2 may include a second driving transistor different from the first driving transistor.

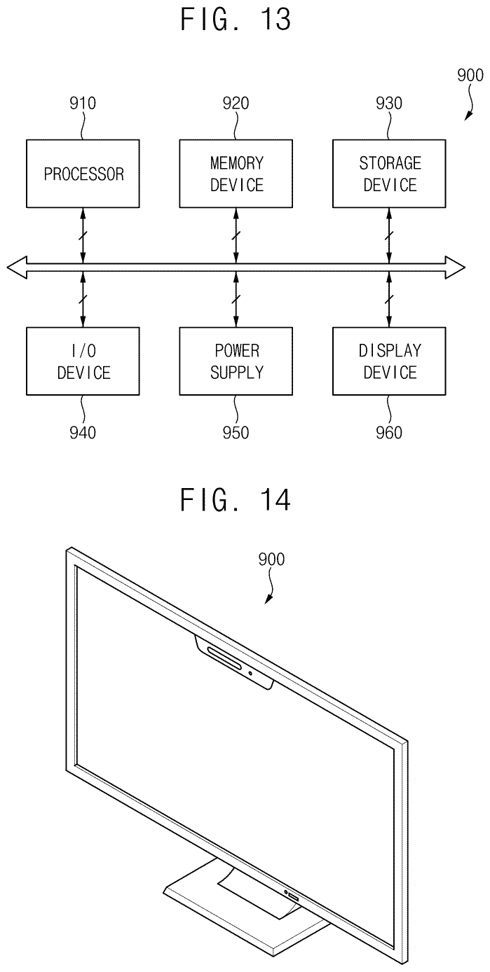

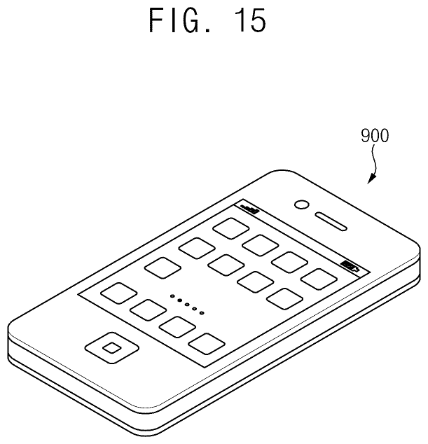

FIG. 13 is a block diagram illustrating an electronic device including the display device of FIG. 1. FIG. 14 is a view illustrating an example in which the electronic device of FIG. 13 is implemented as a television. FIG. 15 is a view illustrating an example in which the electronic device of FIG. 13 is implemented as a smartphone.

Referring to FIGS. 13, 14, and 15, in an embodiment, an electronic device 900 may include a processor 910, a memory device 920, a storage device 930, an input/output device 940, a power supply 950, and a display device 960. For example, the display device 960 may correspond to the display device DD described with reference to FIGS. 1 to 12. The electronic device 900 may further include one or more ports configured to communicate with external components such as a video card, a sound card, a memory card, a USB device, or similar components.

In an embodiment, as shown in FIG. 14, the electronic device 900 may be implemented as a television. In an embodiment, as shown in FIG. 15, the electronic device 900 may be implemented as a smartphone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), or other similar devices that includes a display panel.

The processor 910 may be configured to perform various calculations or tasks for operating the electronic device. In an embodiment, the processor 910 may be a microprocessor, a central processing unit (CPU), an application processor (AP), or a similar processing component. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

In some embodiments, the memory device 920 may store information such as software codes for operating an application program. The application program may include software designed to execute specific tasks or provide functionality to a user. The application program may operate under the control of the processor 910 and utilize data stored in the memory device 920 to deliver a wide range of features, such as productivity tools, multimedia streaming and playback, file or mail deliveries, or communication services. The application program may interact seamlessly with a user interface or a touch screen, allowing a user to launch, navigate, and utilize the program through user inputs such as touch, tap, gesture, or voice interaction.

Upon user selection of an application via a touch screen or user interface, the processor 910 may execute the application program retrieved from the memory device 920 to perform the application's functionalities. For example, when a user selects a camera application by tapping its icon presented on the display device 960, the processor 910 may activate a camera module. Image data acquired through the camera may then be transmitted to the display device 960, which displays the captured image to the user.

As another example, when a user wishes to make a phone call and taps a telephone icon displayed on the display device 960, the processor 910 may execute a phone application stored in the memory device 920. A telephone keypad may then be presented on the display to allow the user to enter a phone number.

As another example, the display device 960 may be integrated into an electronic device 900, such as a laptop computer, smart TV, or tablet. A user wishing to access a multimedia streaming application (e.g., to watch a music video or movie) can do so by tapping the corresponding icon. This action activates the application, allowing the user to view the streamed content.

The memory device 920 may store one or more application programs and various data used by at least one component, such as the processor 910, of the electronic device 900, along with input or output data associated with commands. For example, a camera application, a GPS application, an augmented reality or virtual reality application, and other programs may be executed by the processor 910 upon selection of corresponding icons presented on the display device 960 via a user interface. In addition, the memory device 920 may store various setting data corresponding to user preferences and may include both volatile and non-volatile memory.

The storage device 930 may include a solid state drive (SSD), a hard disk drive (HDD), a CD-ROM, and the like. The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

In some embodiments, the electronic device 900 further includes a user interface. The user interface may serve as the interaction medium between a user and the electronic device 900. The user interface may detect input from a user's body part (e.g., finger), a pen, or a mouse, and generate corresponding electric signals or data values.

In some cases, a fingerprint sensor may sense biometric information such as a user's fingerprint and may also measure one or more biological signals such as blood pressure, skin moisture, or body mass.

In some embodiments, an input sensor may detect various user interactions, including touch, tap, gesture, motion, voice commands, or eye movement. The input sensor may include optical sensors for image capture, eye tracking, and gesture recognition. These optical sensors may use infrared or semiconductor photodetectors. Audio and acoustic sensors, such as MEMS microphones, may also be included for voice-based interactions and can be embedded in the user interface or integrated with the display device 960.

A digitizer may detect coordinate information of input from a pen or a mouse, generating data values corresponding to pointer location or movement. The digitizer may detect passive pen input or communicate with active pens or remote devices.

At least one of the sensors described above may be formed as a layer on top of the display device 960 during the same process used to form display elements such as light-emitting devices or transistors.

The user interface may also include various other sensors, such as a gesture sensor, gyro sensor for rotational motion, acceleration sensor, grip sensor, pressure sensor, proximity sensor, color sensor, infrared emitter and camera for eye tracking, temperature sensor, or a light sensor. These sensors may be particularly suitable for use in AR/VR devices.

The touch screen may include sensors embedded in semiconductor layers of the display device 960, detecting pressure or touch on the screen surface. These sensors may be capacitive or resistive in type and may serve as the primary input method for navigating applications and interacting with the electronic device 900.

As described above, embodiments of the present disclosure have been explained with reference to the accompanying drawings. However, it will be understood by those skilled in the art that various modifications and changes may be made to the present disclosure without departing from the spirit and scope thereof as set forth in the following claims.

The present disclosure can be applied to various display devices which can be equipped with a display device. For example, the present disclosure can be applied to high-resolution smartphones, mobile phones, smart pads, smartwatches, tablet PCs, automobile navigation systems, televisions, computer monitors, laptops, or other electronic devices that include a display device.

What is claimed is:

1. A display device comprising:
a substrate including a display area, wherein the display area includes a light-emitting area and a non-light emitting area at least partially surrounding the light-emitting area;
a pixel driving circuit part including at least one transistor disposed on the substrate in the display area;
an organic insulating layer disposed on the at least one transistor, wherein the organic insulating layer includes a first upper surface substantially flat in a first area of the light-emitting area and a second upper surface inclined at a predetermined slope in a second area of the light-emitting area, and wherein a center region of the second upper surface is at a level different than a level of the first upper surface;
a pixel electrode disposed on the organic insulating layer, wherein the pixel electrode includes a first electrode pattern overlapping the first area and a second electrode pattern overlapping the second area and connected to the pixel driving circuit part;
a pixel defining layer having a pixel opening exposing at least a portion of the pixel electrode; and
a light-emitting layer disposed in the pixel opening.

2. The display device of claim 1, wherein the pixel opening includes a first sub-opening exposing at least a portion of the first electrode pattern, a second sub-opening exposing at least a portion of the second electrode pattern, and the second sub-opening is spaced apart from the first sub-opening, and
the light-emitting layer includes a first sub-light emitting layer disposed on the first electrode pattern and a second sub-light emitting layer disposed on the second electrode pattern.

3. The display device of claim 1, wherein the second electrode pattern is spaced apart from the first electrode pattern.

4. The display device of claim 3, wherein the pixel driving circuit part further includes:
a first connection pattern disposed between the at least one transistor and the organic insulating layer in the second area; and
a second connection pattern disposed between the at least one transistor and the organic insulating layer in the first area, wherein the second connection pattern is connected to the first connection pattern,
wherein the first electrode pattern is connected to the second connection pattern through a first contact hole penetrating the organic insulating layer, and
wherein the second electrode pattern is connected to the first connection pattern through a second contact hole penetrating the organic insulating layer.

5. The display device of claim 4, wherein the second connection pattern is integrally formed with the first connection pattern.

6. The display device of claim 3, wherein the pixel driving circuit part further includes:
a connection pattern disposed between the at least one transistor and the organic insulating layer; and
the connection pattern includes a first portion connected to the first electrode pattern through a first contact hole penetrating the organic insulating layer and a second portion connected to the second electrode pattern through a second contact hole penetrating the organic insulating layer.

7. The display device of claim 6, further comprising:
a controller connected to the second portion of the connection pattern, wherein the controller includes an RLC circuit.

8. The display device of claim 3, wherein the pixel driving circuit part further includes:
a first connection pattern disposed between the at least one transistor and the organic insulating layer in the second area; and
a second connection pattern disposed between the at least one transistor and the organic insulating layer in the first area, wherein the second connection pattern is spaced apart from the first connection pattern,
wherein the first electrode pattern is connected to the second connection pattern through a first contact hole penetrating the organic insulating layer, and
the second electrode pattern is connected to the first connection pattern through a second contact hole penetrating the organic insulating layer.

9. The display device of claim 8, wherein the pixel driving circuit part includes:
a first sub-pixel driving circuit part connected to the second connection pattern, wherein the first sub-pixel driving circuit part includes a first driving transistor; and
a second sub-pixel driving circuit part connected to the first connection pattern, wherein the second sub-pixel driving circuit part includes a second driving transistor.

10. The display device of claim 1, wherein the light-emitting layer includes a light-emitting material configured to emit one of red light, green light, or blue light.

11. A display device comprising:
a substrate including a display area, wherein the display area includes a first light-emitting area, a second light-emitting area, and a third light-emitting area each configured to emit light of different colors, and a non-light emitting area surrounding the first light-emitting area, the second light-emitting area, and the third light-emitting area;
a pixel driving circuit part including at least one transistor disposed on the substrate in the display area;
an organic insulating layer disposed on the at least one transistor, wherein the organic insulating layer includes a first upper surface substantially flat in a first area of each of the first light-emitting area, the second light-emitting area, and the third light-emitting area, and a second upper surface inclined at a predetermined slope in a second area of each of the first light-emitting area, the second light-emitting area, and the third light-emitting area, wherein a center region of the second upper surface is at a level different than a level of the first upper surface;
a first pixel electrode, a second pixel electrode, and a third pixel electrode disposed in each of the first light-emitting area, the second light-emitting area, and the third light-emitting area, respectively, on the organic insulating layer, wherein each of the first pixel electrode, the second pixel electrode, and the third pixel electrode includes a first electrode pattern overlapping the first area and a second electrode pattern overlapping the second area and connected to the pixel driving circuit part;
a pixel defining layer having a pixel opening exposing at least a portion of each of the first pixel electrode, the second pixel electrode, and the third pixel electrode; and
a light-emitting layer disposed in the pixel opening.

12. The display device of claim 11, wherein the second electrode pattern is spaced apart from the first electrode pattern.

13. The display device of claim 11, wherein the pixel driving circuit part includes a first pixel driving circuit part, a second pixel driving circuit part, and a third pixel driving circuit part, and
wherein the first pixel electrode is connected to the first pixel driving circuit part through a first contact hole, the second pixel electrode is connected to the second pixel driving circuit part through a second contact hole, and the third pixel electrode is connected to the third pixel driving circuit part through a third contact hole.

14. The display device of claim 13, wherein:
the first contact hole, the second contact hole, and the third contact hole are sequentially disposed along a first row of the display area,
wherein the first contact hole and the third contact hole are sequentially disposed along a first column of the display area, wherein the first column is perpendicular to the first row, and
wherein the second contact hole is repeatedly disposed along a second column of the display area, wherein the second column is parallel to the first column.

15. An electronic device comprising:
a display device;
a memory device; and
a processor coupled to the memory device, wherein the processor is configured to execute application programs to control the display device;
wherein the display device comprises:
a substrate including a display area, wherein the display area includes a light-emitting area and a non-light emitting area surrounding the light-emitting area;
a pixel driving circuit part including at least one transistor disposed on the substrate in the display area;
an organic insulating layer disposed on the transistor, wherein the organic insulating layer includes a first upper surface substantially flat in a first area of the light-emitting area and a second upper surface inclined at a predetermined slope in a second area of the light-emitting area, and wherein a center region of the second upper surface is at a level different than a level of the first upper surface;
a pixel electrode disposed on the organic insulating layer, wherein the pixel electrode includes a first electrode pattern overlapping the first area and a second electrode pattern overlapping the second area and connected to the pixel driving circuit part;
a pixel defining layer having a pixel opening exposing at least a portion of the pixel electrode; and
a light-emitting layer disposed in the pixel opening.

16. The electronic device of claim 15, wherein:
the pixel opening includes a first sub-opening exposing at least a portion of the first electrode pattern, a second sub-opening exposing at least a portion of the second electrode pattern, and the second sub-opening is spaced apart from the first sub-opening, and
the light-emitting layer includes a first sub-light emitting layer disposed on the first electrode pattern and a second sub-light emitting layer disposed on the second electrode pattern.

17. The electronic device of claim 15, wherein the pixel driving circuit part further includes:
a first connection pattern disposed between the at least one transistor and the organic insulating layer in the second area; and
a second connection pattern disposed between the at least one transistor and the organic insulating layer in the first area, wherein the second connection pattern is connected to the first connection pattern,
wherein the first electrode pattern is connected to the second connection pattern through a first contact hole penetrating the organic insulating layer, and
wherein the second electrode pattern is connected to the first connection pattern through a second contact hole penetrating the organic insulating layer.

18. The electronic device of claim 15, wherein the pixel driving circuit part further includes:
a connection pattern disposed between the at least one transistor and the organic insulating layer; and
the connection pattern includes a first portion connected to the first electrode pattern through a first contact hole penetrating the organic insulating layer and a second portion connected to the second electrode pattern through a second contact hole penetrating the organic insulating layer.

19. The electronic device of claim 18, further comprising:
a controller connected to the second portion of the connection pattern, wherein the controller includes an RLC circuit.

20. The electronic device of claim 15, wherein the pixel driving circuit part further includes:
a first connection pattern disposed between the at least one transistor and the organic insulating layer in the second area;
a second connection pattern disposed between the at least one transistor and the organic insulating layer in the first area, wherein the second connection pattern is spaced apart from the first connection pattern,
a first sub-pixel driving circuit part connected to the second connection pattern, wherein the first sub-pixel driving circuit part includes a first driving transistor; and
a second sub-pixel driving circuit part connected to the first connection pattern, wherein the second sub-pixel driving circuit part includes a second driving transistor.
